(19) United States
(12) Patent Application Publication
(10) Pub. No.: US 2018/0341299 A1
(43) Pub. Date: Nov. 29, 2018

(54) ELECTRONIC DEVICE AND FAN OPERATION METHOD THEREOF

(71) Applicants: Wei-Ning Chai, Taipei City (TW); Li-Fang Chen, Taipei City (TW); Jiun-Yau Wang, Taipei City (TW); Chien-Ming Su, Taipei City (TW); Chang-Yuan Wu, Taipei City (TW)

(72) Inventors: Wei-Ning Chai, Taipei City (TW); I-Chen Chen, Taipei City (TW); Li-Fang Chen, Taipei City (TW); Jiun-Yau Wang, Taipei City (TW); Chien-Ming Su, Taipei City (TW); Chang-Yuan Wu, Taipei City (TW)

(73) Assignee: COMPAL ELECTRONICS, INC., Taipei City (TW)

(21) Appl. No.: 15/986,828

(22) Filed: May 23, 2018

Related U.S. Application Data
(60) Provisional application No. 62/509,751, filed on May 23, 2017.

(51) Int. Cl. G06F 1/20; H05K 7/20

(52) U.S. Cl. CPC G06F 1/203; H05K 7/20209; H05K 7/20172

(57) ABSTRACT

An electronic device, including a main body and a first auxiliary body. The main body includes a processor, a plurality of fans electrically connected to the processor, and a connector electrically connected to the processor. The first auxiliary body is detachably connected to the connector, the processor correspondingly adjusts the heat dissipation capability of at least some of these fans according to the connected first auxiliary body. Further provided is a fan activation method of an electronic device.

### CROSS-REFERENCE TO RELATED APPLICATION

This application claims the priority benefit of U.S. provisional application Ser. No. 62/509,751, filed on May 23, 2017. The entirety of the above-mentioned patent application is hereby incorporated by reference herein and made a part of this specification.

### BACKGROUND OF THE INVENTION

### 1. Field of the Invention

The present invention relates to an electronic device and a fan activation method thereof, in particular, to an activation method for activating different fans according to different electronic devices.

### 2. Description of Related Art

With the technical progress, electronic devices types are becoming more diverse. If a user desires to use different types of electronic devices such as a notebook computer, an electronic entertainment device or a virtual reality machine, the user needs to pay more money for it. In addition, heat dissipation specifications required for different types of electronic devices are different. For example, a required heat dissipation effect may be achieved by probably providing only one to two fans inside a general notebook computer. A required heat dissipation effect may be satisfied by probably providing three to four fans for an electronic entertainment device or a virtual reality machine. Therefore, not only the user needs to pay for these electronic devices respectively, but also these electronic devices occupy a large amount of space due to certain sizes.

### SUMMARY OF THE INVENTION

The present invention provides an electronic device. An auxiliary body thereof is detachably connected to a main body, the electronic device is changeable in type as required, and a processor correspondingly activates these fans according to the connected auxiliary body, so as to meet the heat dissipation requirements of different types of electronic devices.

The present invention provides a fan activation method of an electronic device, which is used to correspondingly activate at least some of fans of a main body according to the type of an auxiliary body, so as to meet the heat dissipation requirements of different types of electronic devices.

An electronic device provided in the present invention includes a main body and a first auxiliary body. The main body includes a processor, a plurality of fans electrically connected to the processor, and a connector electrically connected to the processor. The first auxiliary body is detachably connected to the connector, wherein the processor correspondingly adjusts the heat dissipation capability of at least some of these fans according to the connected first auxiliary body.

In an embodiment of the present invention, the foregoing electronic device further includes a second auxiliary body, detachably connected to the connector, wherein the processor correspondingly activates at least some of these fans according to the connected second auxiliary body.

In an embodiment of the present invention, the number of these fans activated by the processor when the first auxiliary body is connected to the connector is different from the number of these fans activated by the processor when the second auxiliary body is connected to the connector.

In an embodiment of the present invention, the foregoing first auxiliary body includes an assembly of a display screen and an input module, a television or a virtual reality (VR) machine.

In an embodiment of the present invention, the foregoing connector includes a USB Type C connector.

In an embodiment of the present invention, the foregoing processor correspondingly activates at least some of these fans according to the connected first auxiliary body.

In an embodiment of the present invention, the foregoing processor correspondingly changes the revolution speed of at least some of these fans according to the connected first auxiliary body.

A fan activation method of an electronic device provided in the present invention includes: detecting whether a connector of a main body is inserted; determining the type of an auxiliary body connected to the connector; and correspondingly adjusting the heat dissipation capability of at least some of a plurality of fans according to the type of the auxiliary body.

In an embodiment of the present invention, the step of adjusting the heat dissipation capability of at least some of these fans includes: correspondingly changing the revolution speed of at least some of these fans according to the connected auxiliary body.

In an embodiment of the present invention, the step of adjusting the heat dissipation capability of at least some of these fans includes: correspondingly activating at least some of these fans according to the connected auxiliary body.

In an embodiment of the present invention, the number of these fans activated by the processor when the auxiliary body is a first auxiliary body is different from the number of these fans activated by the processor when the auxiliary body is a second auxiliary body.

In an embodiment of the present invention, the auxiliary body includes an assembly of a display screen and an input module, and when the auxiliary body is connected to the connector and is used, with the main body jointly, as a notebook computer, some of these fans are activated.

In an embodiment of the present invention, the foregoing auxiliary body includes a television, and when the auxiliary body is connected to the connector, these fans are activated.

In an embodiment of the present invention, the foregoing auxiliary body includes a virtual reality machine, and when the auxiliary body is connected to the connector, these fans are activated.

Based on the foregoing, the auxiliary body of the electronic device provided in the present invention is detachably connected to the main body, the electronic device is changeable in type as required, and the processor correspondingly adjusts the heat dissipation capability of at least some of these fans according to the connected auxiliary body, so as to meet the heat dissipation requirements of the corresponding electronic device.

In order to make the aforementioned and other objectives and advantages of the present invention comprehensible, embodiments accompanied with figures are described in detail below.

### BRIEF DESCRIPTION OF THE DRAWINGS

FIG. 1 is a schematic diagram of an electronic device according to an embodiment of the present invention.

FIG. 2 is a schematic diagram illustrating separation of a main body and a first auxiliary body of the electronic device in FIG. 1.

FIG. 3 is a schematic diagram of FIG. 2 from another perspective.

FIG. 4 is a schematic diagram of an electronic device according to another embodiment of the present invention.

FIG. 5 is a schematic diagram of an electronic device according to yet another embodiment of the present invention.

FIG. 6 is a flowchart of a fan activation method of an electronic device according to an embodiment of the present invention.

### DESCRIPTION OF THE EMBODIMENTS

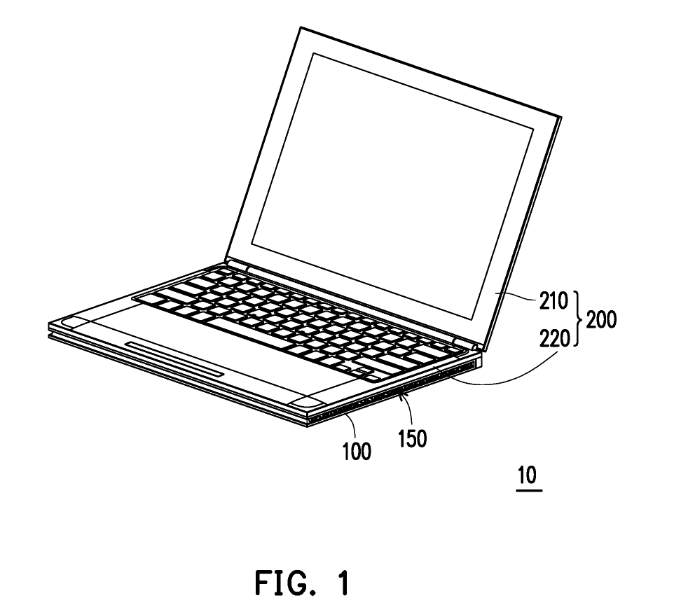

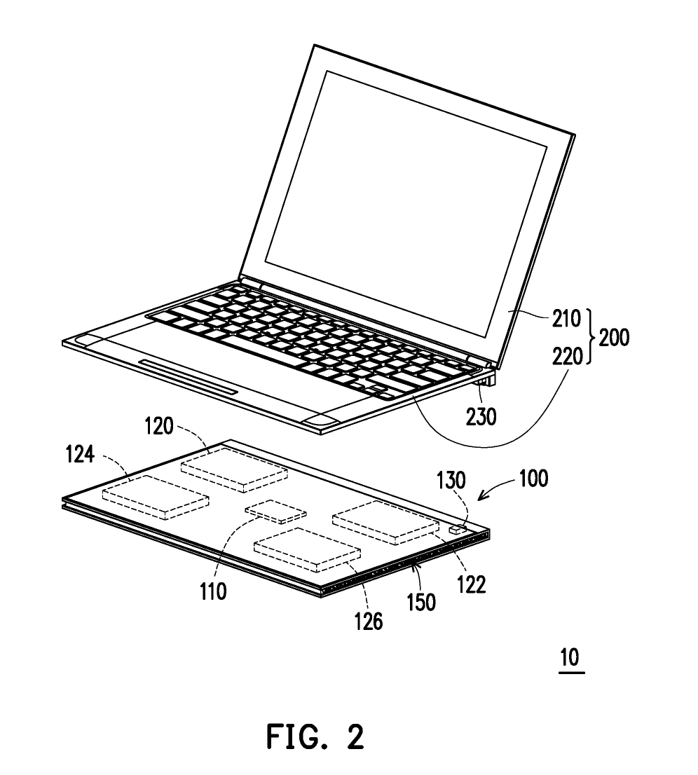

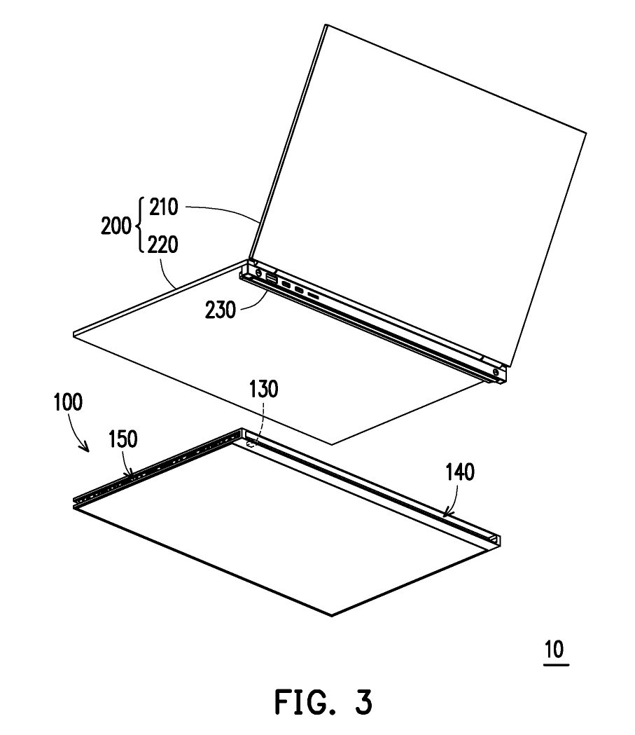

FIG. 1 is a schematic diagram of an electronic device according to an embodiment of the present invention. FIG. 2 is a schematic diagram illustrating separation of a main body and a first auxiliary body of the electronic device in FIG. 1. FIG. 3 is a schematic diagram of FIG. 2 from another perspective.

Referring to FIG. 1 to FIG. 3, an electronic device 10 provided in the present embodiment includes a main body 100 and a first auxiliary body 200. As shown in FIG. 2, in the present embodiment, the main body 100 includes a processor 110, a plurality of fans 120, 122, 124, 126 electrically connected to the processor 110, and a connector 130 electrically connected to the processor 110. The processor 110 may be, for example, a central processing unit (CPU), an embedded controller (EC), a micro control unit (MCU), or other electronic elements. In the present embodiment, the embedded controller (EC) is adopted as the processor 110, the type thereof being not limited to this. The fans 120, 122, 124, 126 are provided inside the main body 100. In the present embodiment, four fans 120, 122, 124, 126 are adopted. Air outlets 150 are provided on two sides of the main body 100. The four fans 120, 122, 124, 126 are provided near the air outlets 150 on two sides respectively. But the number and position of the fans are not limited to this. In the present embodiment, air blown from the fans 120, 122, 124, 126 may leave the main body 100 from the air outlets 150 on two sides to dissipate heat from the main body 100. In addition, in the present embodiment, the connector 130 is, for example, a USB Type C connector 130, but the type of the connector 130 is not limited to this.

As seen from FIG. 2 and FIG. 3, in the present embodiment, the first auxiliary body 200 is detachably connected to the connector 130 of the main body 100. Because the main body 100 includes the processor 110, it may be responsible for a main calculation operation, and the main body 100 may be connected to different auxiliary bodies to serve as different types of electronic devices 10. In the present embodiment, the first auxiliary body 200 includes an assembly of a display screen 210 and an input module 220, and therefore when the main body 100 and the first auxiliary body 200 are combined, the main body 100 and the first auxiliary body 200 may be used jointly as a notebook computer. Of course, the types of the first auxiliary body 200 and the electronic devices 10 are not limited to this.

As shown in FIG. 3, in the present embodiment, a groove 140 is provided at a part of the main body 100, near the connector 130. The first auxiliary body 200 is provided with a boss 230. When the first auxiliary body 200 is assembled on the main body 100, the boss 230 of the first auxiliary body 200 may protrude into the groove 140 of the main body 100 to achieve structural fixing. Of course, in other embodiments, the main body 100 and the first auxiliary body 200 may also achieve structural fixing in other manners such as magnetic attraction, which is not limited to this. In addition, a connector (not shown) of the first auxiliary body 200 may also be inserted into the connector 130 of the main body 100, so as to be electrically connected to the main body 100.

The processor 110 of the main body 100 may correspondingly adjust the heat dissipation capability of at least some of these fans 120, 122, 124, ‘126 according to the connected auxiliary body. In particular, in the present embodiment, after the first auxiliary body 200 is connected to the connector 130 of the main body 100, the connector 130 may transfer received type information about the first auxiliary body 200 to the processor 110, and after determining the type of the first auxiliary body 200, the processor 110 may correspondingly activate a required number of fans or fans at required positions according to the type of the first auxiliary body 200 or adjust the revolution speed of the fans.

In the present embodiment, the first auxiliary body 200 is an assembly of a display screen 210 and an input module 220, and the main body 100 and the first auxiliary body 200 are used jointly as a notebook computer. The processor 110 may determine, according to a preset form, that the running state of the processor 110 is at a medium-low degree when the first auxiliary body 200 is an assembly of a display screen 210 and an input module 220. For example, there are two fans to be activated, specifically referring to the two fans 120, 122 located at the top of the figure. In the present embodiment, because both hands of a user may approach the two fans 124, 126 at the bottom of the figure when the electronic device 10 is a notebook computer, the two fans 124, 126 at the bottom of the figure are not activated in order to avoid discomfort caused by blowing of hot air to the hands of the user when the user is activating the notebook computer. Of course, in other embodiments, the electronic device 10 is a notebook computer, different fans or fans at different positions may also be activated, which is not limited to this. In other embodiments, the processor 110 may also instruct, according to the type of the first auxiliary body 200, the fans to run at a medium-low revolution speed.

In the present embodiment, because the first auxiliary body 200 is removable from the main body 100, when the user desires to convert the type of the electronic device 10 to another type, the user only needs to remove the first auxiliary body 200 from the main body 100 and then installs another auxiliary body onto the main body 100, so that the electronic device may be changed into another electronic device 10a or 10b. This will be described below.

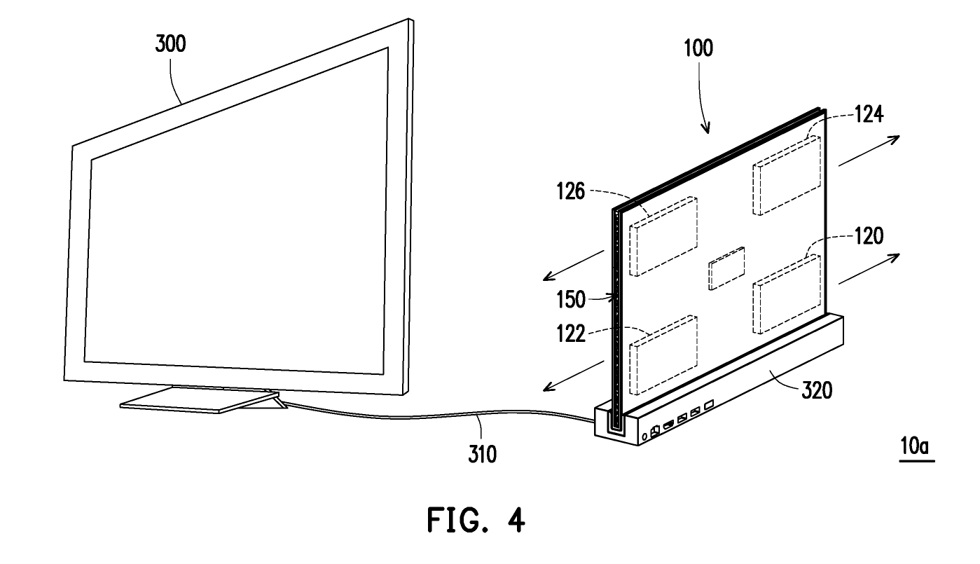

FIG. 4 is a schematic diagram of an electronic device according to another embodiment of the present invention. Referring to FIG. 4, in the present embodiment, the main body 100 is used as, for example, an electronic entertainment device. The electronic device 10a includes a second auxiliary body 300, the second auxiliary body 300 being detachably connected to the connector 130 of the main body 100. In the present embodiment, the second auxiliary body 300 includes a display device (such as a television or a display screen). When the main body 100 is connected to the second auxiliary body 300, image or sound information may be output to the second auxiliary body 300. In the present embodiment, the electronic device 10a may also optionally include a supporting seat 320, which is used to support the main body 100, and may enable the main body 100 to stand so as to reduce a desktop occupying ratio. The supporting seat 320 may also be electrically connected to the main body 100. A port may be provided on the supporting seat 320, and allows insertion of an external device.

In the present embodiment, the main body 100 is electrically connected to the supporting seat 320 when being inserted to the supporting seat 320, and the supporting seat 320 is then connected to the second auxiliary body 300 with the aid of a connecting wire 310, so as to output the image or sound information to the second auxiliary body 300. Of course, in other embodiments, the main body 100 may also be directly connected to the second auxiliary body 300 without the aid of the supporting seat 320.

In the present embodiment, the processor 100 (shown in FIG. 2) correspondingly adjusts the heat dissipation capability of at least some of these fans 120, 122, 124, 126 (shown in FIG. 2) according to the connected second auxiliary body 300. For example, after the second auxiliary body 300 is connected to the connector 130 (shown in FIG. 2) of the main body 100, the connector 130 may transfer received type information about the second auxiliary body 300 to the processor 110, and the processor 110 may correspondingly activate a required number of fans or fans at required positions according to the type of the second auxiliary body 300 after determining the type of the second auxiliary body 300. For example, in the present embodiment, the second auxiliary body 300 is a television, the main body 100 may be preset as an electronic entertainment device when being connected to the television, and it is under a heavy gaming situation, and high-power operation is required. Therefore, the processor 110 may activate, for example, four fans according to a preset form. In other words, the processor 110 may activate all fans 120, 122, 124, 126. Of course, in other embodiments, settings made within the processor 110 may also be different, and will not be limited to the foregoing. In other embodiments, the processor 110 may also instruct the fans to run at a high revolution speed according to the type of the second auxiliary body 300.

As seen from the present embodiment and the previous embodiment, as the first auxiliary body 200 and the second auxiliary body 300 are different in type, the number of these fans activated by the processor 110 when the first auxiliary body 200 is connected to the connector 130 of the main body 100 may be different from the number of these fans activated by the processor 110 when the second auxiliary body 300 is connected to the connector 130 of the main body 100. In this way, besides achieving the required heat dissipation effect of different electronic devices 10, 10a, since the main body 100 (including the processor 110 and at least some fans 120, 122) of different electronic devices 10, 10a is shared, the required overall cost may be reduced as long as a user pays for the main body 100 and the required secondary body, and a smaller space may also be occupied.

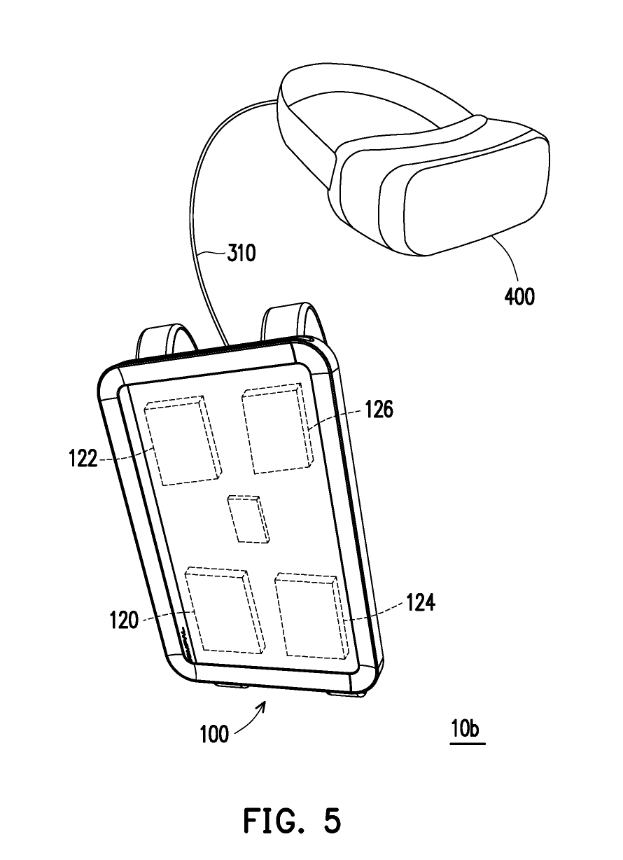

FIG. 5 is a schematic diagram of an electronic device according to yet another embodiment of the present invention. Referring to FIG. 5, in the present embodiment, the electronic device 10b includes the main body 100 and a third auxiliary body 400, the third auxiliary body 400 being detachably connected to the connector 130 of the main body 100. In the present embodiment, the third auxiliary body 400 includes a virtual reality (VR) machine. Likewise, the processor 100 (shown in FIG. 2) may correspondingly adjust the heat dissipation capability of at least some of these fans 120, 122, 124, 126 (shown in FIG. 2) according to the connected second auxiliary body 300.

In the present embodiment, after the third auxiliary body 400 is connected to the connector 130 of the main body 100, the connector 130 may transfer received type information about the third auxiliary body 400 to the processor 110, and after determining the type of the third auxiliary body 400, the processor 110 may correspondingly activate a required number of fans or fans at required positions according to the type of the third auxiliary body 400 or adjust the revolution speed of the fans. For example, in the present embodiment, the third auxiliary body 400 is a virtual reality machine, it is under a heavy gaming situation, and high-power operation is required. Therefore, the processor 110 may activate, for example, four fans according to a preset form. In other words, the processor 110 may activate all fans 120, 122, 124, 126. Of course, in other embodiments, settings made within the processor 110 may also be different, and will not be limited to the foregoing. In other embodiments, the processor 110 may also instruct the fans to run at a high revolution speed according to the type of the third auxiliary body 400.

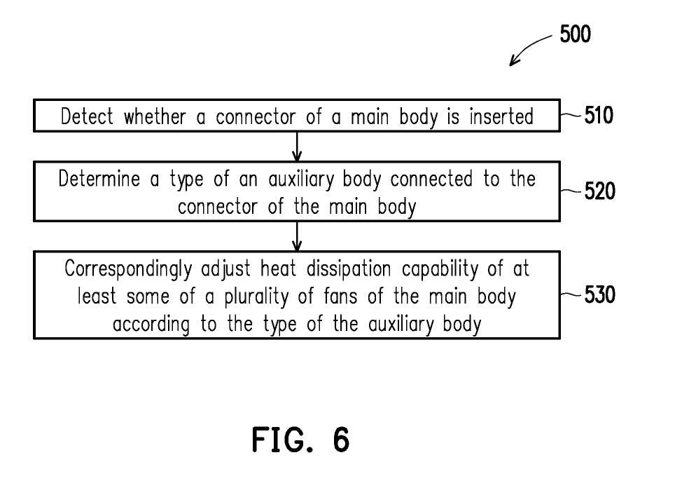

FIG. 6 is a flowchart of a fan activation method of an electronic device according to an embodiment of the present invention. Referring to FIG. 6, a fan activation method 500 of an electronic device provided in the present embodiment includes the following steps. First, it is detected whether a connector of a main body is inserted (step 510). Then, the type of an auxiliary body connected to the connector of the main body is determined (step 520). Finally, the heat dissipation capability of at least some of a plurality of fans of the main body is correspondingly adjusted according to the type of the auxiliary body (step 530).

In particular, a manner of adjusting the heat dissipation capability of at least some of these fans of the main body refers, for example, to activating different number of fans or fans at different positions. For example, as shown in FIG. 2, if the auxiliary body includes an assembly of a display screen 210 and an input module 220, when the auxiliary body is connected to the connector 130 of the main body and is used, with the main body 100 jointly, as a notebook computer, some of these fans 120, 122, 124, 126 of the main body are activated. For example, two fans 120, 122 among four fans 120, 122, 124, 126 of the main body may be activated. For another example, as shown in FIG. 4, if the auxiliary body includes a television, the main body 100 may be used as an electronic entertainment device when being connected to the television. When the auxiliary body is connected to the connector 130 (shown in FIG. 2) of the main body, four fans 120, 122, 124, 126 (shown in FIG. 2) of the main body will be all activated. For another example, as shown in FIG. 5, if the auxiliary body includes a virtual reality machine, when the auxiliary body is connected to the connector 130 (shown in FIG. 2) of the main body, four fans 120, 122, 124, 126 (shown in FIG. 2) of the main body will be all activated. Of course, the type of the auxiliary body and the number and position of activated fans are not limited to the foregoing. In other embodiments, a manner of adjusting the heat dissipation capability of at least some of these fans of the main body refers, for example, to changing the revolution speed of at least one fan.

Based on the foregoing, the auxiliary body of the electronic device provided in the present invention is detachably connected to the main body, the electronic device is changeable in type as required, and the processor of the main body correspondingly adjusts the heat dissipation capability of at least some of these fans according to the connected auxiliary body, so as to meet the heat dissipation requirements of the corresponding electronic device.

Although the present invention has been disclosed with the embodiments as above, they are not intended to limit the present invention. Any person skilled in the art may make some variations and modifications without departing from the spirit and scope of the present invention. Therefore, the protection scope of the present invention should be defined by the appended claims.

What is claimed is:

1. An electronic device, comprising:
a main body, comprising a processor, a plurality of fans electrically connected to the processor, and a connector electrically connected to the processor; and
a first auxiliary body, detachably connected to the connector,
wherein the processor correspondingly adjusts the heat dissipation capability of at least some of these fans according to the connected first auxiliary body.

2. The electronic device according to claim 1, further comprising:
a second auxiliary body, detachably connected to the connector,
wherein the processor correspondingly activates at least some of these fans according to the connected second auxiliary body.

3. The electronic device according to claim 2, wherein the number of these fans activated by the processor when the first auxiliary body is connected to the connector is different from the number of these fans activated by the processor when the second auxiliary body is connected to the connector.

4. The electronic device according to claim 1, wherein the first auxiliary body comprises an assembly of a display screen and an input module, a display device or a virtual reality (VR) machine.

5. The electronic device according to claim 1, wherein the connector comprises a USB Type C connector.

6. The electronic device according to claim 1, wherein the processor correspondingly activates at least some of these fans according to the connected first auxiliary body.

7. The electronic device according to claim 1, wherein the processor correspondingly changes the revolution speed of at least some of these fans according to the connected first auxiliary body.

8. A fan activation method of an electronic device, comprising:
detecting whether a connector of a main body is inserted;
determining a type of an auxiliary body connected to the connector; and
correspondingly adjusting the heat dissipation capability of at least some of a plurality of fans according to the type of the auxiliary body.

9. The fan activation method of an electronic device according to claim 8, wherein the step of adjusting the heat dissipation capability of at least some of these fans comprises:
correspondingly changing the revolution speed of at least some of these fans according to the connected auxiliary body.

10. The fan activation method of an electronic device according to claim 8, wherein the step of adjusting the heat dissipation capability of at least some of these fans comprises:
correspondingly activating at least some of these fans according to the connected auxiliary body.

11. The fan activation method of an electronic device according to claim 10, wherein the number of these fans activated by the processor when the auxiliary body is a first auxiliary body is different from the number of these fans activated by the processor when the auxiliary body is a second auxiliary body.

12. The fan activation method of an electronic device according to claim 10, wherein the auxiliary body comprises an assembly of a display screen and an input module, and when the auxiliary body is connected to the connector and is used, with the main body jointly, as a notebook computer, some of these fans are activated.

13. The fan activation method of an electronic device according to claim 10, wherein the auxiliary body comprises a display device, and when the auxiliary body is connected to the connector, these fans are activated.

14. The fan activation method of an electronic device according to claim 10, wherein the auxiliary body comprises a virtual reality machine, and when the auxiliary body is connected to the connector, these fans are activated.
